(19) United States
(12) Patent Application Publication
(10) Pub. No.: US 2026/0025924 A1
(43) Pub. Date: Jan. 22, 2026

(54) ROUTING OF HIGH-SPEED TRACES BASED ON DIRECTIONALITY OF RETURN CURRENT

(71) Applicant: DELL PRODUCTS L.P., Round Rock, TX (US)

(72) Inventors: Soumya Singh, Bangalore (IN); Seema P K, Bangalore (IN); Bhyrav Mutnury, Round Rock, TX (US); Junho Joo, Rolla, MO (US)

(21) Appl. No.: 18/776,883

(22) Filed: Jul. 18, 2024

(51) Int. Cl. H05K 1/11; H01P 3/08; H05K 1/02

(52) U.S. Cl. CPC H05K 1/115; H01P 3/081; H05K 1/0237; H05K 2201/09618

(57) ABSTRACT

A printed circuit board, comprising a trace disposed within the printed circuit board, a power via proximate to the trace, and a ground via positioned proximate to the power via such that a return current directionality is orthogonal to the trace.

### FIELD OF THE DISCLOSURE

The present disclosure generally relates to information handling systems, and more particularly relates to routing of high-speed traces based on directionality of return current.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A printed circuit board, comprising a trace disposed within the printed circuit board, a power via proximate to the trace, and a ground via positioned proximate to the power via such that a return current directionality is orthogonal to the trace.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system, according to an embodiment of the present disclosure;

FIGS. 2-6 are diagrams of a printed circuit board for routing of high-speed traces based on directionality of return current, according to an embodiment of the present disclosure;

FIGS. 7-8 are flowcharts of methods for routing of high-speed traces based on directionality of return current, according to an embodiment of the present disclosure; and

FIG. 9 is a block diagram of an information handling system, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Information handling systems may include one or more printed circuit boards (PCBs). Currently, the density of the PCB design layout is increasing. For example, the PCBs may include a large number of conductive traces to route signals to and between various components of the information handling system. In addition, the PCBs also include through holes that are used as vias for signal trace routing transitions between different PCB layers and power energy delivery between layers. Further, a key consideration in the PCB design layout includes maintaining the information handling system in high operation stability by preventing critical signals from being impaired by noise. Accordingly, noise margins have become stringent to a few millivolts and a few picoseconds.

In server platforms, multiphase buck converters are used to provide power to a central processing unit and other components. However, the switching nature of voltage regulator modules generates high-frequency noise. Due to the complexity of the PCB design layouts, high-speed signals are usually routed in the vicinity of a voltage regulator region which results in inductive coupling because of leaked return current on the ground surface. Typically, the present approach to reduce noise associated with the inductive coupling is to route the signal trace as far as possible. However, this is not always possible. Another approach typically used is to put ground vias around the affected region of the voltage regulator module. However, this is also not always possible due to the density of PCB design layouts. To address this issue, the present disclosure provides a system and method to address the noise associated with the coupling by taking into account the directionality of the return current.

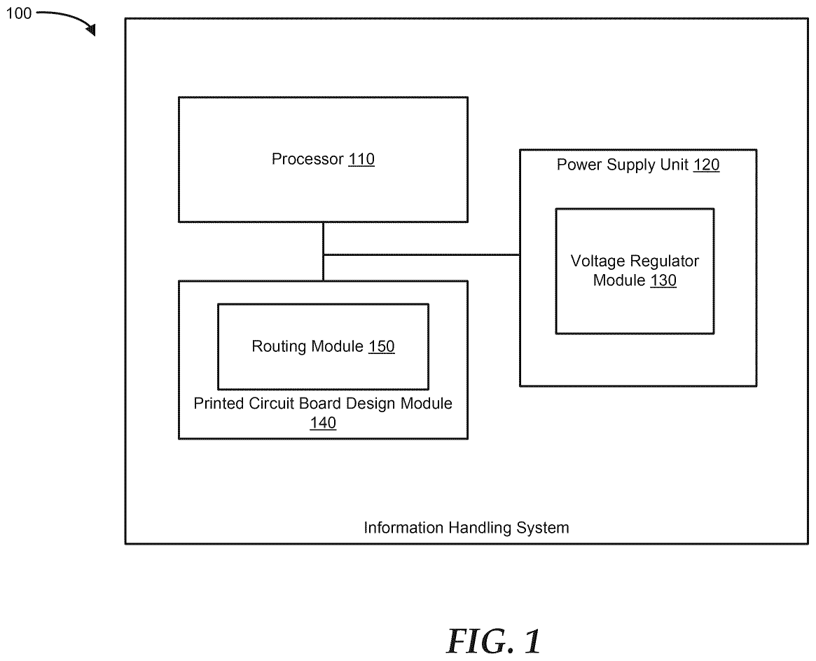

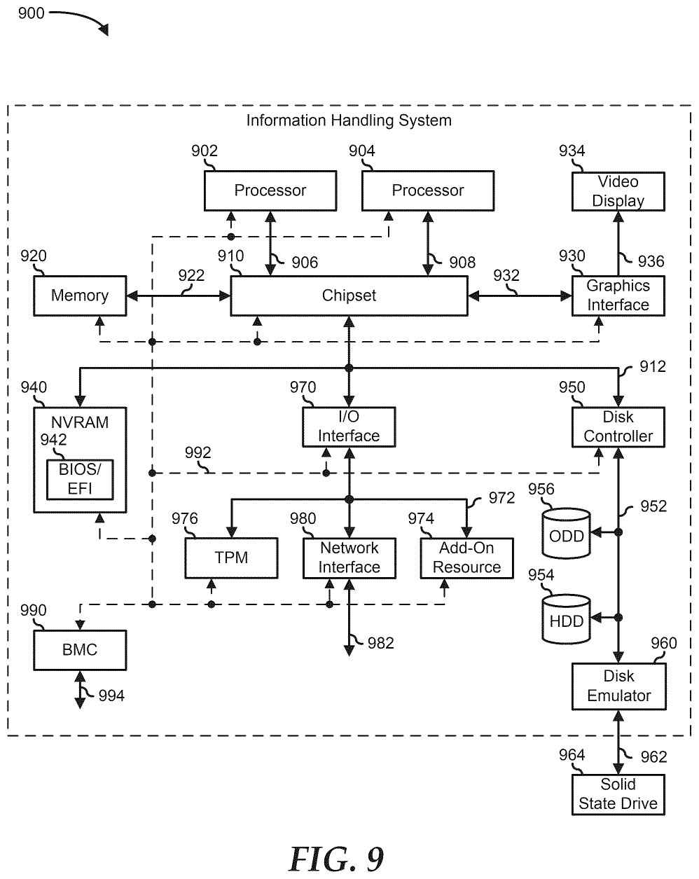

FIG. 1 shows a portion of an information handling system 100 for routing of high-speed traces based on directionality of return current. Information handling system 100, which is similar to information handling system 900 of FIG. 9, includes a processor 110, a power supply unit 120, and a PCB design module 140. Power supply unit 120 includes a voltage regulator module 130. PCB design module 140 includes a routing module 150. Processor 110 may be coupled to power supply unit 120 and routing module 150. Accordingly, power supply unit 120 is coupled to PCB design module 140 and processor 110. Other connections between components may be omitted for descriptive clarity.

Power supply unit 120 may be configured to provide power to components of information handling system 100, such as processor 110. Voltage regulator module 130 may be a multi-phase voltage regulator configured to regulator power provided to processor 110. Voltage regulator module 130 may receive electrical power from power supply unit 120 and regulate the electrical power to a lower voltage. For example, voltage regulator module 130 may receive approximately 12 volts of direct current (DC) from power supply unit 120 and regulate the received power to approximately 1.0 or 2.0 volts DC or any other voltage for use by processor 110. Accordingly, voltage regulator module 130 may be configured to provide a power signal, such as an output current to processor 110.

Although not specifically shown, information handling system 100 may include one or more PCBs, according to one or more embodiments. For example, one or more components of information handling system 100 may be implemented using hardware circuitry on one or more PCBs. The hardware circuitry may include components soldered onto the PCB, as well as conductive traces etched into a conductive layer of the PCB. For example, a PCB may include multiple conductive layers, each comprising conductive traces for carrying current and traces for carrying data signals of various data signal types, including high-speed data signals. In various embodiments, the conductive layers may be distributed on respective sides of one or more substrate layers of the PCB or between alternating substrate layers of the PCB. For example, the PCB may be single-sided, double-sided, or multi-layered. A PCB may couple two or more devices to one another. For example, the PCB may include one or more traces that couple two or more devices to one another. In some embodiments, traces in a first conductive layer may be coupled to traces in a second conductive layer using one or more vias. In at least some embodiments, power vias may deliver current to and between the conductive layers.

Some existing information handling systems that include switching voltage regulators use voltage regulator module vias, also referred to herein simply as power vias, for current energy delivery on the PCB power plane between two layers. For example, a number of the power vias may be placed together and close to an integrated power stage silicon chip to convey current to the other signal layers. The number of the power vias for each power stage integrated circuit may be determined by the maximum sustainable current of each power stage integrated circuit in accordance with design requirements. The more power vias that are used together, the lower the voltage drop between layers. However, placing these power vias together requires a relatively large area on the PCB. In addition, the traces cannot run too close to these power vias because the switching behavior can induce large amounts of noise energy, potentially impacting the signal integrity of the adjacent signals.

Processor 110, which is similar to processors 902 and 904 of FIG. 9 may perform any suitable operations including but not limited to PCB design module 140 and routing module 150. PCB design module 140 may be configured to facilitate a design layout of traces and connections of PCBs. Routing module 150 may be configured to facilitate routing of high-speed traces based on a directionality of an expected return current. In particular, routing module 150 may determine where to place the PCB one or more ground vias based on the expected return current directionality, wherein the return current corresponds to a signal current that flows between power and ground vias. The ground via is electrically coupled to a ground plane or layer of the PCB to provide a ground reference for signals transferred across a layer. The ground plane serves as a return path for the current. Thus, the ground via may provide an electrical shield to the power vias, thereby increasing signal quality. As such, the ground via may also be referred to as a ground shielding via. The ground via may be disposed several mils away from signal vias and/or power vias. Routing of the high-speed signal trace, power vias, and/or the ground via need to be optimized to achieve a best possible signal quality within certain physical limits.

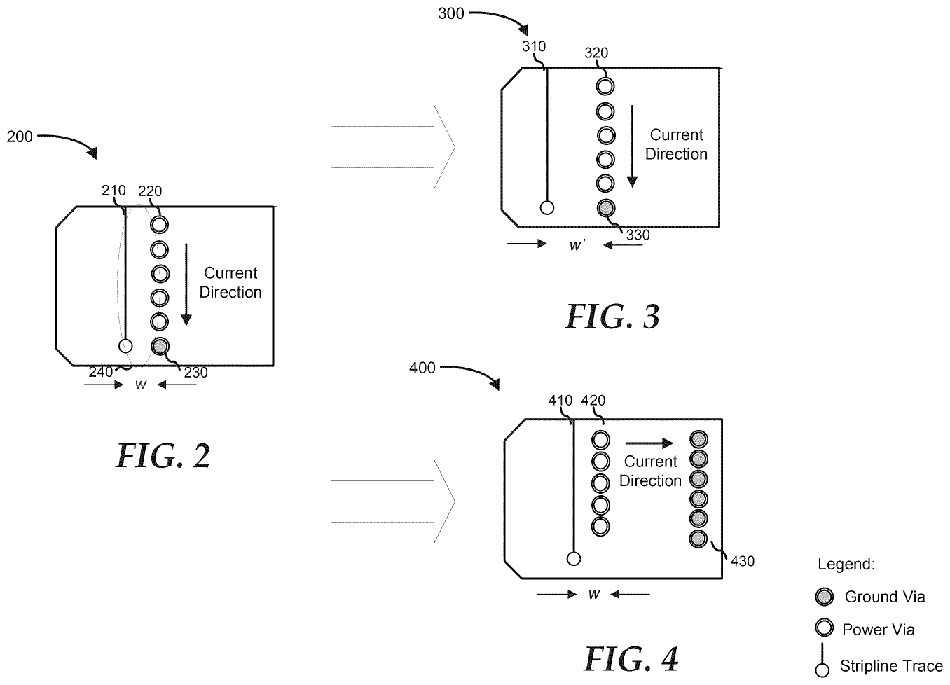

Although examples shown herein show stripline traces, also referred to herein simply as stripline, one of skill in the art that the present disclosure may include microstrips instead of the striplines without varying from the scope of the present disclosure. Those of ordinary skill in the art will appreciate that the configuration, hardware, and/or software components of PCB 200 depicted in FIG. 2 may vary. For example, the illustrative components within PCB 200 are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for continuity of the description.

FIG. 2 shows a view of selected elements of a portion of a PCB 200 of an information handling system, which is similar to information handling system 900 of FIG. 9. PCB 200 includes a stripline 210, a set of power vias 220, and a ground via 230. Distance of stripline 210 to set of power vias 220 and ground via 230 is indicated by width “w.” Set of power vias 220 may be used for signal trace routing transitions for power energy delivery between different layers. Thus, set of power vias 220 may be a source of unwanted noise, impedance discontinuities, and electromagnetic interference induced by a switching behavior of the voltage regulator, as depicted by an electrical field 240. PCBs often employ local ground vias proximate to signal vias to control the impedance noise and minimize coupling to neighboring power vias, as depicted by ground via 230. Because of a relative location of ground via 230 relative to set of power vias 220, the expected dominant direction of the current signal is indicated by an arrow.

PCBs often utilize striplines, such as stripline 210, which are data signal transmission line traces suspended in a dielectric medium between two ground layers. Due to the proximity of stripline 210 to set of power vias 220 and ground via 230, in addition to the current direction, there is a possibility of inductive coupling. Accordingly, stripline 210 may pick up some noise, which can affect the signal integrity of the high-speed signal associated with stripline 210. To minimize or reduce the inductive coupling, stripline 210 location may be adjusted. For example, stripline 210 may be moved farther from set of power vias 220 and ground via 230 as depicted in FIG. 3, wherein a new distance of stripline 210 is indicated by width “w′.” In this example, width w′ may be wider than width w of FIG. 1.

However, the design layout of the PCBs may not allow stripline 210 to be moved farther from set of power vias 220. Accordingly, a set of ground vias may be positioned, such that the expected direction of the return current is orthogonal relative to stripline 210, such as depicted in a PCB 400 of FIG. 4. The location of the ground vias which allows for a return path for the current provides for good signal integrity by reducing crosstalk. In this example, a distance of stripline 410 to set of power vias 420 and ground via 430 is indicated by width “w,” which is similar to the width w of FIG. 2. In addition, the position of the ground vias may adhere to one or more pre-defined spacing between the ground vias and the power vias.

FIG. 3 shows a view of selected elements of a portion of PCB 300 of an information handling system, which is similar to information handling system 900 of FIG. 9. PCB 300 includes a stripline 310, a set of power vias 320, and a ground via 330, wherein ground via 330 is linearly aligned with set of power vias 320. Further, ground via 330 may be positioned relative to set of power vias 320 according to specification. In this example, ground via 330 is positioned wherein the dominant direction of the expected return current is parallel to stripline 310. However, because width “w” between stripline 310 and set of power vias 320, the effect of the noise associated with the inductive coupling to stripline 310 may be reduced or minimized. Accordingly, the signal integrity associated with stripline 310 may be maintained.

FIG. 4 shows a view of selected elements of a portion of PCB 400 of an information handling system, which is similar to information handling system 900 of FIG. 9. PCB 400 includes a stripline 410, a set of power vias 420, and a ground via 430, wherein ground via 430 is parallel with set of power vias 420 and stripline 410. Further, ground via 430 may be positioned relative to set of power vias 320 according to specification. In this example, ground via 430 is positioned wherein the dominant direction of the expected return current is orthogonal to stripline 410. Accordingly, the effect of the noise associated with the inductive coupling to stripline 310 may be reduced or minimized. Accordingly, the signal integrity associated with stripline 310 may be maintained.

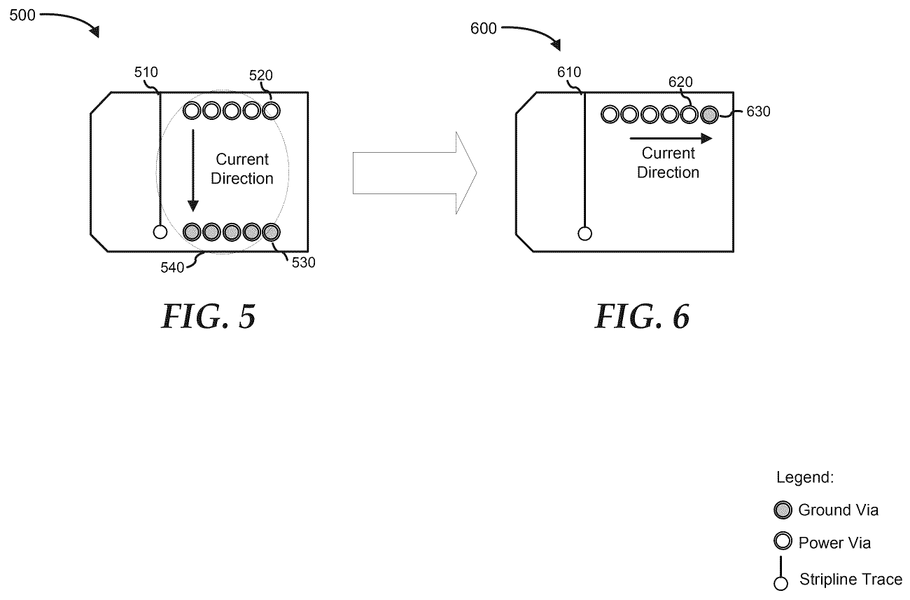

FIG. 5 shows a view of selected elements of a portion 500 of a PCB of an information handling system, which is similar to information handling system 900 of FIG. 9. Section 500 includes a stripline 510, a set of power vias 520, and a set of ground vias 530. In this example, set of ground vias 530 is positioned wherein the current direction is parallel to stripline 510. Because of the relative location of set of ground vias 530 relative to set of power vias 520, the dominant direction of a current signal is indicated by an arrow. Due to the proximity of stripline 210, there is a possibility of inductive coupling as indicated by an electrical field 540. Accordingly, stripline 210 may pick up some noise, which can affect the signal integrity of stripline 210. To minimize or reduce the inductive coupling, the directionality of the expected return current may be adjusted such that the dominant direction of the expected current is orthogonal to the stripline. Accordingly, the position of one or more ground vias may be adjusted, such that the expected current may be directed orthogonally away from the stripline, such as depicted in a PCB 600 of FIG. 6.

FIG. 6 shows a view of selected elements of a portion of a PCB 600 of an information handling system, which is similar to information handling system 900 of FIG. 9. PCB 600 includes a stripline 610, a set of power vias 620, and a ground via 630, wherein ground via 430 is linearly aligned with set of power vias 620. Further, ground via 630 may be positioned relative to set of power vias 620 according to specification. In this example, ground via 530 is positioned wherein the dominant direction of the expected current is orthogonal to stripline 510. Accordingly, inductive coupling that may affect stripline 610 may be minimized or reduced.

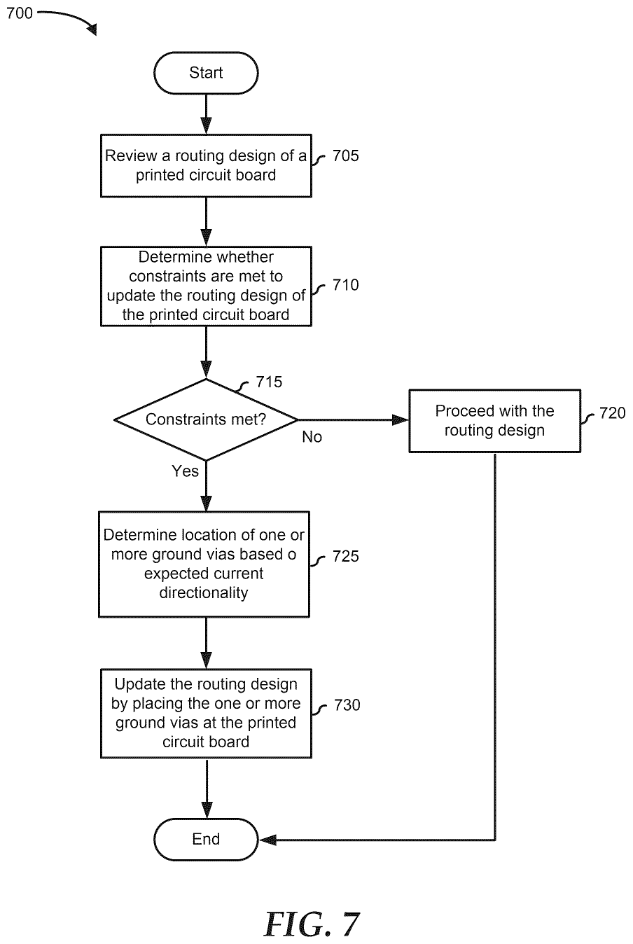

FIG. 7 shows a flowchart of method 700 for routing of high-speed traces based on directionality of the return current. Method 700 may be performed on one or more sections of a PCB with a high-speed signal trace in proximity to one or more power vias, such the signal integrity associated with the high-speed signal trace may be affected. Method 700 may be performed by any suitable component of information handling system 100 of FIG. 1, including but not limited to PCB design module 140 of FIG. 1. While embodiments of the present disclosure are described in terms of the components of information handling system 100 of FIG. 1, it should be recognized that other components may be utilized to perform the described method. One of skill in the art will appreciate that this flowchart explains a typical example, which can be extended to applications or services in practice. In addition, it will be readily appreciated that not every method step set forth in this flowchart is always necessary and that certain steps of the methods may be combined, performed simultaneously, in a different order, or perhaps omitted, without varying from the scope of the disclosure.

Method 700 typically starts at block 705 where a PCB design module may initiate and/or review routing design of high-speed signal traces. In this example, placement of one or more high-speed signal traces and power vias may be initially determined. Further, inductive coupling and its effect on signal integrity based on the placement of the high-speed signal traces and the power vias may be determined. Accordingly, if the inductive coupling may affect the signal integrity of the high-speed signal, the PCB design module may initiate a routing module to determine whether the routing may be updated to reduce noise associated with the inductive coupling.

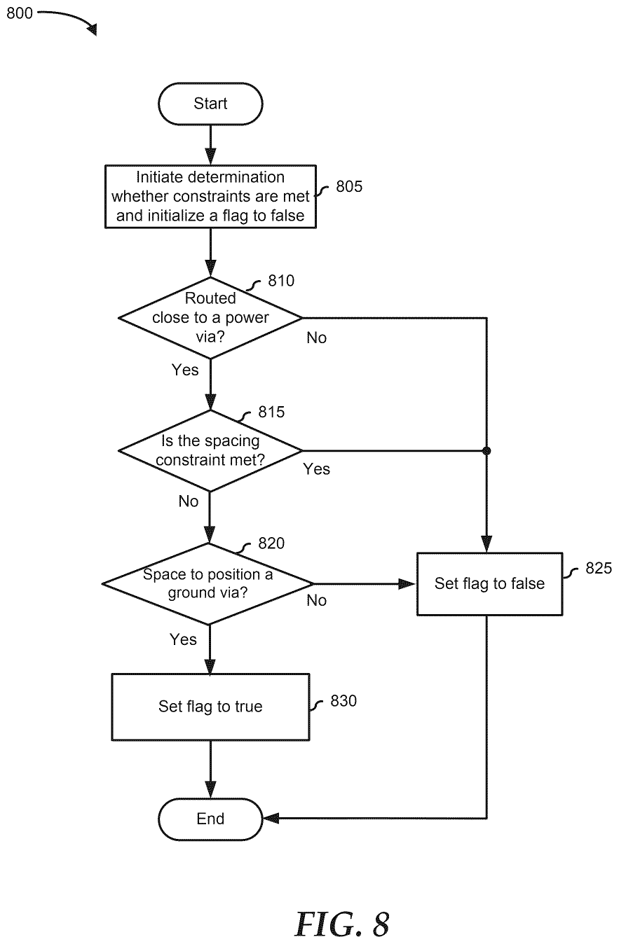

At block 710, the routing module may determine whether the present location of the high-speed signal trace and power modules met one or more constraints, such as spacing between the high-speed signal trace and one or more power vias. This is performed to determine whether updating the present PCB routing can be updated. Block 710 is shown in greater detail by a flowchart of a method 800 of FIG. 8.

At decision block 715, the routing module may determine whether the constraints to update the routing design are met. The routing module may check the value of a flag to determine whether to proceed with updating the routing designs to include one or more ground vias. In one example, the flag may be set to true, which indicates that the constraints are met, and the routing module can proceed to update the present routing design using one or more ground vias. Otherwise, if the flag is set to false, then the constraints are not met. If the constraints are met, then the “YES” branch is taken and method 700 proceeds to block 720. If the constraints are not met, then the “NO” branch is taken and method 700 proceeds to block 725. At block 720, the PCB design module may proceed with the present routing design of the PCB. The PCB with its components, such as traces, power vias, and ground vias may be formed according to the routing design. Afterwards, the method ends.

At block 725, the routing module may determine a location of one or more ground vias based on the expected directionality of the return current according to the placement of the ground via(s). Routing of high-speed trace signals on a densely populated PCB is typically challenging due to various restrictions or constraints. Because the ground via is expected to draw the current to its direction, the ground via may be placed such that the expected directionality of the return is orthogonal to the high-speed signal trace. This is done to minimize the effect of inductive coupling on the high-speed signal trace, minimizing crosstalk and effect with signal integrity.

The position of the ground via may be determined based on the location of the power vias and/or the power vias. In one example, if there is space for the stripline to be moved away from the set of power vias and the present ground via, then the stripline may be moved away from the power vias and the ground via. The space between the new location of the stripline and the power vias and/or the ground via may be determined according to specification. A stripline may be moved as depicted in FIG. 3.

In another example, if there is not enough space to position the stripline farther away from the power vias and the power vias are in parallel with the high-speed signal trace, then one or more ground vias may be placed in parallel to the power vias, wherein the power vias are in between the ground vias and the high-speed signal trace. The space between the power vias and the ground vias should meet the requirement of PCB routing design. The position of the ground vias may draw the return current towards the ground vias as depicted in FIG. 4. Accordingly, noise due to inductive coupling may be reduced and/or minimized as the return current is directed away orthogonally from the high-speed signal trace.

In yet another example, if the power vias are orthogonal to the stripline, then at least one ground via may be positioned in linear alignment with the power vias that are farther from the stripline as depicted in FIG. 6. Similar to the above, the return current in this design is directed away orthogonally from the high-speed signal trace. At block 730, the routing module may update the design of the PCB as determined in block 710. The PCB with its components, such as traces, power vias, and ground vias may be formed according to the updated design. Afterwards, the method ends.

FIG. 8 shows a flowchart of method 800 for determining whether constraints are met to update the routing design of the PCB. Method 800 illustrates block 710 of FIG. 7 in greater detail. One of skill in the art will appreciate that this flowchart diagram explains a typical example, which can be extended to applications or services in practice. In addition, it will be readily appreciated that not every method step set forth in this flowchart is always necessary and that certain steps of the methods may be combined, performed simultaneously, in a different order, or perhaps omitted, without varying from the scope of the disclosure.

Method 800 typically starts at block 805 where the routing module may determine whether constraints that may prevent implementation to update the present routing design are met. One of skill will appreciate that additional constraints may be added without materially departing from the novel teachings and advantages of the embodiments of the present disclosure. A flag to indicate whether to proceed with updating the routing design to include one or more ground vias is met may be initialized to false.

At decision block 810, the routing module may determine whether the high-speed signal trace is routed close to the power vias. For example, the routing module may determine whether the high-speed signal trace is routed close to the power vias such that inductive coupling may have an adverse effect on the signal associated with the high-speed signal trace. If the high-speed signal trace is routed close to a power via, then the “YES” branch is taken, and the method proceeds to decision block 815. If the high-speed signal trace is not routed close to a power via, then the “NO” branch is taken, and the method proceeds to decision block 825.

At decision block 815, the routing module may determine whether the spacing constraint between the high-speed signal trace and the power vias of the present routing design is met. The spacing constraint may define the minimum space between the high-speed signal trace and the power vias according to specification. If the spacing constraint is met, then the “YES” branch is taken, and the method proceeds to block 825. If the spacing constraint is not met, then the “NO” branch is taken, and the method proceeds to decision block 820.

At decision block 820, the routing module may determine whether there is enough space to position one or more ground vias. For example, the routing module may determine whether there is enough space to drill a ground via. In addition to spacing constraints around the ground via. If there is enough space to position one or more ground vias, then the “YES” branch is taken, and the method proceeds to block 830. If there is not enough space to position one or more ground vias, then the “NO” branch is taken, and the method proceeds to block 825. At block 825 the flag is set to false. At block 830, the flag is set to true. Afterwards, the method ends.

FIG. 9 illustrates a generalized embodiment of an information handling system 900 including processors 902 and 904, a chipset 910, a memory 920, a graphics adapter 930 connected to a video display 934, a non-volatile RAM (NVRAM) 940 that includes a basic input and output system/extensible firmware interface (BIOS/EFI) module 942, a disk controller 950, a hard disk drive (HDD) 954, an optical disk drive 956, a disk emulator 960 connected to a solid-state drive (SSD) 964, an input/output (I/O) interface 970 connected to an add-on resource 974 and a trusted platform module (TPM) 976, a network interface 980, and a baseboard management controller (BMC) 990. Processor 902 is connected to chipset 910 via processor interface 906, and processor 904 is connected to the chipset via processor interface 908. In a particular embodiment, processors 902 and 904 are connected together via a high-capacity coherent fabric, such as a HyperTransport link, a QuickPath Interconnect, or the like. Chipset 910 represents an integrated circuit or group of integrated circuits that manage the data flow between processors 902 and 904 and the other elements of information handling system 900. In a particular embodiment, chipset 910 represents a pair of integrated circuits, such as a northbridge component and a southbridge component. In another embodiment, some or all of the functions and features of chipset 910 are integrated with one or more of processors 902 and 904.

Memory 920 is connected to chipset 910 via a memory interface 922. An example of memory interface 922 includes a Double Data Rate (DDR) memory channel and memory 920 represents one or more DDR Dual In-Line Memory Modules (DIMMs). In a particular embodiment, memory interface 922 represents two or more DDR channels. In another embodiment, one or more of processors 902 and 904 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 920 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 930 is connected to chipset 910 via a graphics interface 932 and provides a video display output 936 to a video display 934. An example of a graphics interface 932 includes a Peripheral Component Interconnect-Express (PCIe) interface and graphics adapter 930 can include a four-lane (×4) PCIe adapter, an eight-lane (×8) PCIe adapter, a 16-lane (×16) PCIe adapter, or another configuration, as needed or desired. In a particular embodiment, graphics adapter 930 is provided down on a system PCB. Video display output 936 can include a Digital Video Interface (DVI), a High-Definition Multimedia Interface (HDMI), a DisplayPort interface, or the like, and video display 934 can include a monitor, a smart television, an embedded display such as a laptop computer display, or the like.

NVRAM 940, disk controller 950, and I/O interface 970 are connected to chipset 910 via an I/O channel 912. An example of I/O channel 912 includes one or more point-to-point PCIe links between chipset 910 and each of NVRAM 940, disk controller 950, and I/O interface 970. Chipset 910 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 940 includes BIOS/EFI module 942 that stores machine-executable code (BIOS/EFI code) that operates to detect the resources of information handling system 900, to provide drivers for the resources, to initialize the resources, and to provide common access mechanisms for the resources. The functions and features of BIOS/EFI module 942 will be further described below.

Disk controller 950 includes a disk interface 952 that connects the disc controller to a hard disk drive (HDD) 954, to an optical disk drive (ODD) 956, and to disk emulator 960. An example of disk interface 952 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 960 permits SSD 964 to be connected to information handling system 900 via an external interface 962. An example of external interface 962 includes a USB interface, an institute of electrical and electronics engineers (IEEE) 1394 (Firewire) interface, a proprietary interface, or a combination thereof. Alternatively, SSD 964 can be disposed within information handling system 900.

I/O interface 970 includes a peripheral interface 992 that connects the I/O interface to add-on resource 974, to TPM 976, and to network interface 980. Peripheral interface 972 can be the same type of interface as I/O channel 912 or can be a different type of interface. As such, I/O interface 970 extends the capacity of I/O channel 912 when peripheral interface 972 and the I/O channel are of the same type, and the I/O interface translates information from a format suitable to the I/O channel to a format suitable to the peripheral interface 972 when they are of a different type. Add-on resource 974 can include a data storage system, an additional graphics interface, a network interface card (NIC), a sound/video processing card, another add-on resource, or a combination thereof. Add-on resource 974 can be on a main circuit board, on separate circuit board, or add-in card disposed within information handling system 900, a device that is external to the information handling system, or a combination thereof.

Network interface 980 represents a network communication device disposed within information handling system 900, on a main circuit board of the information handling system, integrated onto another component such as chipset 910, in another suitable location, or a combination thereof. Network interface 980 includes a network channel 982 that provides an interface to devices that are external to information handling system 900. In a particular embodiment, network channel 982 is of a different type than peripheral interface 972 and network interface 980 translates information from a format suitable to the peripheral channel to a format suitable to external devices.

In a particular embodiment, network interface 980 includes a NIC or host bus adapter (HBA), and an example of network channel 982 includes an InfiniBand channel, a Fibre Channel, a Gigabit Ethernet channel, a proprietary channel architecture, or a combination thereof. In another embodiment, network interface 980 includes a wireless communication interface, and network channel 982 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 982 can be connected to an external network resource (not illustrated). The network resource can include another information handling system, a data storage system, another network, a grid management system, another suitable resource, or a combination thereof.

BMC 990 is connected to multiple elements of information handling system 900 via one or more management interface 992 to provide out of band monitoring, maintenance, and control of the elements of the information handling system. As such, BMC 990 represents a processing device different from processor 902 and processor 904, which provides various management functions for information handling system 900. For example, BMC 990 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 990 can vary considerably based on the type of information handling system. BMC 990 can operate in accordance with an Intelligent Platform Management Interface (IPMI). Examples of BMC 990 include an Integrated Dell® Remote Access Controller (iDRAC).

Management interface 992 represents one or more out-of-band communication interfaces between BMC 990 and the elements of information handling system 900, and can include an Inter-Integrated Circuit (I²C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 900, that is apart from the execution of code by processors 902 and 904 and procedures that are implemented on the information handling system in response to the executed code.

BMC 990 operates to monitor and maintain system firmware, such as code stored in BIOS/EFI module 942, option ROMs for graphics adapter 930, disk controller 950, add-on resource 974, network interface 980, or other elements of information handling system 900, as needed or desired. In particular, BMC 990 includes a network interface 994 that can be connected to a remote management system to receive firmware updates, as needed or desired. Here, BMC 990 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 990 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 990, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 990 is included on a main circuit board (such as a baseboard, a motherboard, or any combination thereof) of information handling system 900 or is integrated onto another element of the information handling system such as chipset 910, or another suitable element, as needed or desired. As such, BMC 990 can be part of an integrated circuit or a chipset within information handling system 900. An example of BMC 990 includes an iDRAC, or the like. BMC 990 may operate on a separate power plane from other resources in information handling system 900. Thus, BMC 990 can communicate with the management system via network interface 994 while the resources of information handling system 900 are powered off. Here, information can be sent from the management system to BMC 990 and the information can be stored in a RAM or NVRAM associated with the BMC. Information stored in the RAM may be lost after power-down of the power plane for BMC 990, while information stored in the NVRAM may be saved through a power-down/power-up cycle of the power plane for the BMC.

Information handling system 900 can include additional components and additional busses, not shown for clarity. For example, information handling system 900 can include multiple processor cores, audio devices, and the like. While a particular arrangement of bus technologies and interconnections is illustrated for the purpose of example, one of skill will appreciate that the techniques disclosed herein are applicable to other system architectures. Information handling system 900 can include multiple central processing units (CPUs) and redundant bus controllers. One or more components can be integrated together. Information handling system 900 can include additional buses and bus protocols, for example, I²C and the like. Additional components of information handling system 900 can include one or more storage devices that can store machine-executable code, one or more communications ports for communicating with external devices, and various input and output (I/O) devices, such as a keyboard, a mouse, and a video display.

For purposes of this disclosure, information handling system 900 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 900 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 900 can include processing resources for executing machine-executable code, such as processor 902, a programmable logic array (PLA), an embedded device such as a System-on-a-Chip (SoC), or other control logic hardware. Information handling system 900 can also include one or more computer-readable media for storing machine-executable code, such as software or data.

Although FIG. 7 and FIG. 8 show example blocks of methods 700 and 800 in some implementations, methods 700 and 800 may include additional blocks, fewer blocks, different blocks, or differently arranged blocks than those depicted in FIGS. 7 and 8. Those skilled in the art will understand that the principles presented herein may be implemented in any suitably arranged processing system. Additionally, or alternatively, two or more of the blocks of methods 700 and 800 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A printed circuit board, comprising:
a trace disposed within the printed circuit board;
a power via proximate to the trace; and
a ground via positioned proximate to the power via such that a return current directionality is orthogonal to the trace.

2. The printed circuit board of claim 1, wherein the trace is a stripline.

3. The printed circuit board of claim 1, wherein the trace is a microstrip.

4. The printed circuit board of claim 1, wherein the power via is a voltage regulator module via.

5. The printed circuit board of claim 1, wherein the ground via is a ground shielding via.

6. The printed circuit board of claim 1, wherein the ground via is linearly aligned with the power via.

7. The printed circuit board of claim 1, wherein the power via is disposed between the trace and the ground via.

8. The printed circuit board of claim 1, wherein the ground via is disposed in parallel with the power via.

9. An information handling system, comprising:
a printed circuit board comprising:
a trace disposed within the printed circuit board;
a power via proximate to the trace; and
a ground via positioned proximate to the power via such that a return current directionality is orthogonal to the trace.

10. The information handling system of claim 9, wherein the trace is a stripline.

11. The information handling system of claim 9, wherein the power via is a voltage regulator module via.

12. The information handling system of claim 9, wherein the ground via is a ground shielding via.

13. The information handling system of claim 9, wherein the ground via is linearly aligned with the power via.

14. The information handling system of claim 9, wherein the power via is disposed between the trace and the ground via.

15. The information handling system of claim 9, wherein the ground via is disposed in parallel with the power via.

16. A method comprising:
forming a trace disposed within a printed circuit board;
forming a power via proximate to the trace; and
forming a ground via positioned proximate to the power via such that a return current directionality is orthogonal to the trace within the printed circuit board.

17. The method of claim 16, wherein the trace is a stripline.

18. The method of claim 16, wherein the power via is a voltage regulator module via.

19. The method of claim 16, wherein the ground via is a ground shielding via.

20. The method of claim 16, wherein the ground via is linearly aligned with the power via.
